(19) United States
(12) Patent Application Publication
(10) Pub. No.: US 2022/0113340 A1
(43) Pub. Date: Apr. 14, 2022

(54) SYSTEM AND METHOD FOR AUTONOMOUSLY DETECTING SIGNALS ACROSS A RADIO SPECTRUM

(71) Applicant: ASRC FEDERAL HOLDING COMPANY, LLC, Beltsville, MD (US)

(72) Inventors: Steve Thomas KACENJAR, Moorestown, NJ (US); Ronald Alan NEELY, JR., Moorestown, NJ (US); Aaron DANT, Columbia, MD (US)

(73) Assignee: ASRC FEDERAL HOLDING COMPANY, LLC, Beltsville, MD (US)

(21) Appl. No.: 17/500,271

(22) Filed: Oct. 13, 2021

Related U.S. Application Data
(60) Provisional application No. 63/091,025, filed on Oct. 13, 2020.

(51) Int. Cl. G01R 23/167; H04W 24/10; H04B 1/00; H04B 17/391; H04L 27/00

(52) U.S. Cl. CPC G01R 23/167; H04W 24/10; H04L 27/0006; H04B 17/391; H04B 1/0003

(57) ABSTRACT

A signal detection methodology is provided to determine from a waterfall image where the signal occurred on the frequency spectrum, when it occurred, and what type of modulation the signal is. The methodology includes converting a waterfall image into a first binary image version of the waterfall image; removing noise spikes from the first binary image version of the waterfall image; removing vertical gaps in the first binary image to thereby create an intermediate image version of the first binary image; converting the intermediate image version of the first binary image into a second binary image; identifying location parameters of a signal of interest within the second binary image; and isolating, using the identified location parameters, the signal of interest in the waterfall image to generate an isolated image of the signal of interest.

### CROSS REFERENCE TO RELATED APPLICATIONS

The instant application claims priority to US Provisional application entitled SYSTEM AND METHOD FOR AUTONOMOUSLY DETECTING SIGNALS ACROSS A RADIO SPECTRUM, filed Oct. 13, 2020, the entire contents of which are incorporated herein by reference.

### FIELD OF THE INVENTION

The instant application relates to a methodology for automatically detecting the locations of radio signals within a radio spectrum. More specifically, the instant application relates to a methodology that analyzes image data from a software defined radio (SDR) to automatically identify the frequency location and time of simultaneous modulated radio transmissions.

### BRIEF DESCRIPTION OF THE RELEVANT ART

In the past, signal detection has been performed using manual audio discovery by ear or more recently using electrical sequential scanners. The latter approach would only provide the location of RF signals but would not provide any information about the extent to which these signals occupied the RF domain. In addition, these methods were sequential and could not simultaneously look across extended regions of the RF space. SDR based technology offers a new avenue to provide simultaneous and wide RF Spectrum surveillance that can be exploited to find RF traffic location and signal properties.

### BACKGROUND OF THE INVENTION

The FCC plays a role in the allocation, management, and implementation of requirements for the radio spectrum. One of the FCC's goals is to ensure the radio spectrum is utilized in the most effective way for the benefit of the public. Across the radio spectrum several forms of competing services exist. Some examples are broadcast radio and television, satellite, radar, WLAN and Bluetooth; and amateur radio. There is also an exponentially increasing demand for cellular services. Actual bandwidth utilization data is imperative for making informed allocation decisions. In addition, to best cope with dynamic congestion of the Radio Frequency (RF) bands, new technologies such as cognitive radio require prompt assessment of real-time RF band traffic.

To meet these requirements, the FCC assessment and the Cognitive Radio operation needs to know the “three W's” of different types of signals—when it occurs, what frequency it is at, and what type of encoding it is (e.g., Morse Code, commercial radio stations, television, radar, etc.) This information allows for the identification of areas of potential expansion and allocation of new services to the radio spectrum as well as providing cognitive radio open sections of the Radio Frequency (RF) spectrum to operate.

Currently a primary methodology for identifying the three W's is visual observation of the output of a software defined radio (SDR), such as shown by SDR 100 in FIG. 1. SDR is a radio communication system where components that have been traditionally implemented in hardware (e.g. mixers, filters, amplifiers, modulators/demodulators, detectors, etc.) are instead implemented by software on a personal computer, embedded system, or dispersed over a network. In particular, an SDR is a collection of hardware and software technologies where some or all the radio's operating functions (also referred to as physical layer processing) are implemented through modifiable software or firmware operating on programmable processing technologies. These devices include Analog-to-Digital Converters (ADC), Digital-to-Analog Converters, field programmable gate arrays (FPGA), digital signal processors (DSP), general purpose processors (GPP), programmable System on Chip (SoC), or other application specific programmable processors.

A feature of many communication SDR systems is that they can display all radio signals associated within a defined frequency range on its Panadapter Display Panel, such as the one shown in radio signal graph 200 in FIG. 2. This display provides a frequency axis that is in the horizontal direction while the signal strength is plotted in the vertical direction. Peaks 202 in the radio spectrum are coincident with the presence of radio transmissions at that frequency and represents the information of interest. The valleys 204 between the spikes are generally noise.

Graph 200 represents a snapshot of radio signals at a moment in time, however, these signals are not always active, and this the graph will look different from moment to moment. By way of example, if the radio transmission has an active voice, then the peak or localized elevated region will appear, yet if no one is speaking over the radio then there is no transmission and thus no peak. In another example, for Morse Code if the dot or dash is being transmitted the peak will appear, but in the space between the next dot or dash there is no transmission and thus the spectrum will show only background noise at that frequency. Thus, depending on how the information signal is encoded, the time-pattern observed in the signal display will change as the transmitted information changes. The precise encoding of how the signal will change is defined by a set of standard instructions. There are many such unique instruction sets called modulations which provide instructions to transmitters on how to encode the transmitted information. For a given identical piece of information, each modulation type will provide different temporal visualization as seen on the SDR signal display.

FIG. 2 also shows that multiple signals can co-exist across an RF band. Single-detection methods will not provide the required information need by the FCC or for real-time cognitive radio needs. A detection method that locates and time tags RF signals must also be able to sense all RF activity in real or near real-time. Thus, the detection method must be agile enough to be able to detect any number of RF signatures operating across a user-specified RF band in real or non-real-time.

A low-cost method for achieving simultaneous detection and localization of signal activity is to digitally capture the image produced by SDR devices. In such displays, visual recording of all RF signal activity is recorded and can be exploited using image processing methods. These signal activities can show many unique features that characterize the type of radio transmission is used during the transmission. A fundamental attribute that defines the patterns of such features is how the signal is modulated. Modulations can be thought of as a set of special instructions to a transmitter as to how to transmit the information.

These modulation instructions provide unique patterns if they are photographed over time and laid next to each other. Such representations are also displayed on an SDR and are often referred to as “waterfalls”. FIG. 3 shows when the signal display 302 (upper portion of the graph) is connected to the waterfall display 303 (lower portion of the graph) a complete picture of the RF space is represented.

The signal display 302 presents a graphical summary of the RF signal activity during one sample period across the frequency domain. Some signals take up a large bandwidth of the frequency spectrum during a sample period (e.g., LSB modulation, FT8) while others take up relatively small regions of the frequency spectrum (e.g., Morse Code peaks).

Every time the signal is sampled in the signal display 302, it is appended to the top of the waterfall display and increments the waterfall display down by one-pixel unit. Thus, the waterfall display 303 appears to fall downward over time much like a waterfall.

The waterfall display 303 shows how different signals and noises in signal display 302 generate different types of waterfalls. The richness of variations are governed by the RF modulation types being used during the data transmission. Examples of some examples of various modulation types are provided in 304, 305, 306, and 308-312. The width of any particular waterfall along the horizontal axis 310 is tied to a local band of frequency defining their bandwidth. For example, waterfall 304 shows a wide-bandwidth signal that occupies a range of frequencies 311 from about 7.098 MHz to 7100 MHz while waterfall 309 occupies a very narrow range of frequencies 311 at about 7.060 MHz. Such information can be identified and recorded by a skilled human operator such as shown in the signal display 302 and/or waterfall display 303. The operator can visually identify peaks of signals of interest provided they are high enough to be visually discernable from the background noise.

There are, however, practical limits on what a human operator can discern from visual observation. For example, there are several concurrent signals happening simultaneously over vast ranges of the frequency spectrum. This is extremely labor intensive and would require a large team of trained analysts to perform the “When” and “Where” Operations (WWO) of signals of interest.

### BRIEF DESCRIPTION OF THE DRAWINGS

Various embodiments in accordance with the present disclosure will be described with reference to the drawings, in which:

FIG. 1 shows a prior art SDR.

FIG. 2 shows a radio frequency spectrum graph from an SDR.

FIG. 3 shows a radio frequency spectrum graph in combination with its waterfall image.

FIG. 4 illustrates an image being converted to a binary image.

FIG. 5 illustrates an image subject to image erosion.

FIG. 6 shows a flowchart of an embodiment of the invention.

FIG. 7 is a flowchart of Calibration of the SDR according to an embodiment of the invention.

FIG. 8 shows more detail of a frequency calibration methodology.

FIG. 9 shows more detail of a time calibration methodology.

FIGS. 10A-C illustrate the effects of a signal contrast methodology.

FIG. 11 shows an impact of stack summing on SDR Display noise according to an embodiment of the invention.

FIG. 12 shows an impact of stacking on SDR Display when both signal and noise are present.

FIG. 13 is a flowchart of a methodology for identifying the location and nature of signals of interest with a received radio spectrum according to an embodiment of the invention.

FIG. 14 shows the evolution of waterfall images as processed by the flowchart of FIG. 13.

FIG. 15 shows data provided by morphological processing of the processed binary image.

FIGS. 16 and 17 show examples of signal isolation and extraction from the original waterfall image.

FIG. 18 shows an example of time tagging a waterfall image.

FIG. 19 is a flowchart and transformational drawing of converting time tags in the waterfall image of FIG. 18 into an equation that establishes the relationship between a Y-coordinate on the waterfall image and the time that the data was sampled for that Y-coordinate.

FIGS. 20 and 21 show a flowchart and corresponding an example of image transformation and processing to identify the start and stop times for specific signals.

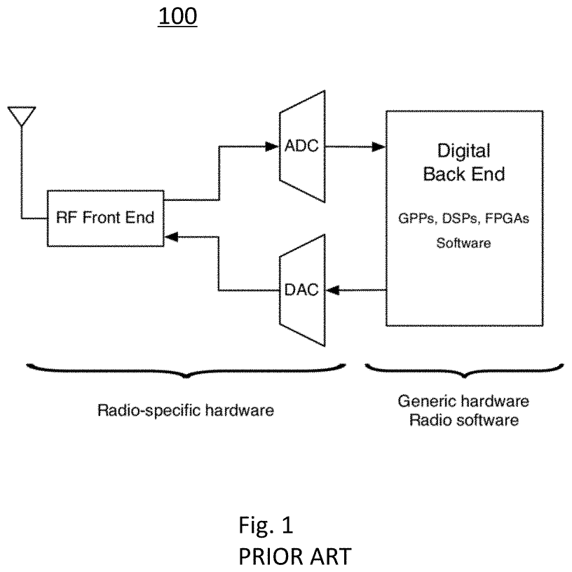

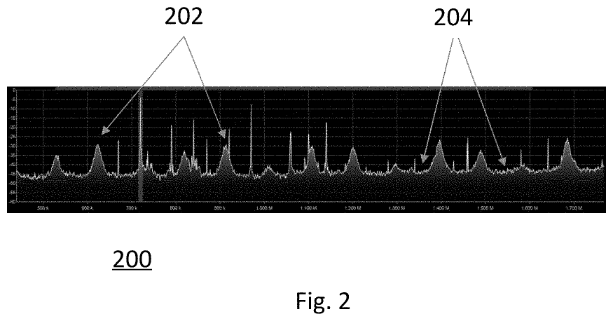

The patent or application file contains at least one drawing executed in color. Copies of this patent or patent application publication with color drawing(s) will be provided by the Office upon request and payment of the necessary fee.

### DETAILED DESCRIPTION

In the following description, various embodiments will be illustrated by way of example and not by way of limitation in the figures of the accompanying drawings. References to various embodiments in this disclosure are not necessarily to the same embodiment, and such references mean at least one. While specific implementations and other details are discussed, it is to be understood that this is done for illustrative purposes only. An individual skilled in the relevant art will recognize that other caps and configurations may be used without departing from the scope and spirit of the claimed subject matter.

The term “substantially” is defined to be essentially conforming to the dimension, shape, or other feature that the term modifies, such that the component need not be exact. For example, “substantially cylindrical” means that the object resembles a cylinder but can have one or more deviations from a true cylinder. Substantially “parallel” “perpendicular” or the like are preferably within about 5-10 degrees of ideal. Distances or sizes referred to as “substantially the same” or the like are less than about ±5%, preferably less than about ±3%, particularly less than 0.01-inch variation, and most particularly identical to thousands of an inch scale

The term “comprising” when utilized, means “including, but not necessarily limited to”; it specifically indicates open-ended inclusion or membership in the so-described combination, group, series and the like. The term “a” means “one or more” absent express indication that it is limited to the singular. “First,” “second,” etc. are labels to differentiate like terms from each other and does not imply any order or numerical limitation.

Used herein “horizontal” “vertical,” “diagonal,” “top,” “bottom,” “upper,” “lower” and the like are to provide a frame of reference for portions of the embodiments to be described relative to each other, and not to absolute space. Thus, for example a surface may be described as horizontal so another surface can be described and diagonal or vertical relative thereto. However, such frames of reference do not limit the scope of the invention, e.g., rotating cap to a different orientation does not change the special relationship.

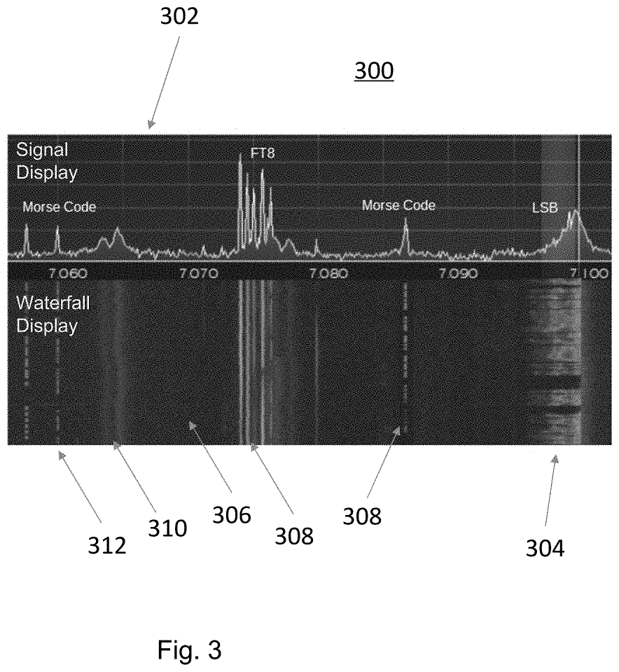

“Waterfall image” refers to the image of a waterfall signature such as illustrated in FIG. 3 and encompasses the various states that such data may be represented. By way of non-limiting example, this may be the image as displayed, or the underlying image data itself as resident in memory that can be accessed and displayed.

“Gray-scale image” refers to the single value representation for a pixel in an image. By way of non-limiting example, an 8-bit gray-scale image will have 256 distinct values with the value of zero assigned to black and a value of 255 for white. All other values between these two limits correspond to various shades of gray. The nature of such data representations is well known in the art and not discussed further herein.

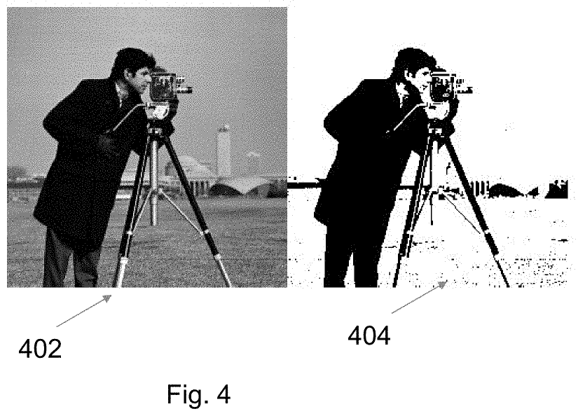

Referring now to FIG. 4, “binary image” refers to a two-color image. The embodiments herein primarily are directed to black and white as the two colors, but as discussed below the invention is not limited to those colors. In the context of black/white, as illustrated in FIG. 4 refers to the result of mapping of a gray-scale image 402 by converting the intermediate gray-scale pixels in 402 into black (e.g., value zero) or white (e.g., value 255) depending on if they are above or below a user-defined gray-scale threshold. The nature of such conversion methods is well known in the art and not discussed further herein. The resulting binary image 404 would include only black or white pixels.

“Morphological operations” are mathematical operations applied to imagery. Non-limiting examples are operations that segment, dilute, erode, or extract other geometric quantities off image structures.

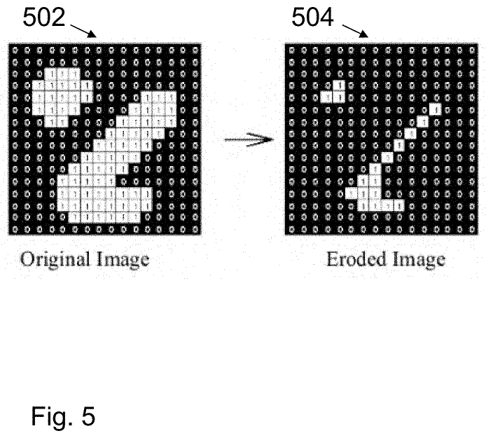

“Erosion operation” refers to a type of morphological image operation that evaporates small regions of the scene leaving only the larger regions remaining. By way of non-limiting example, FIG. 5 shows an original image 502 which is subject to one or more erosion operations to arrive at the eroded image 504. The process trims the perimeter of white pixels along the periphery and converts them into black pixels; the particular pixels so converted are based on the nature of the image and the particular parameters of the erosion operation.

It is to be understood that the various graphs and waterfall images as shown in the figures and discussed herein are snapshots in time relative to the presence of signals. Any graph and waterfall images will to some extent be unique from moment to moment. The various graphs and waterfall images are thus shown to represent format and not specific content unless otherwise specifically stated. It is also to be understood that the various graphs and/or waterfalls may or may not be copied from the SDR display but rather, from Application Programming Interface (API) data directly provided by the SDR, either of which may be provided in real-time or previously stored in memory.

Embodiments herein are generally directed to automatically identifying the “three W's” of different types of signals—when it occurs, what frequency it is at, and what type of encoding it is. The methodology is robust can detect most or all types of waterfall RF signatures. It can detect and localize both narrow band transmissions such as Morse Code as well as broadband transmissions such as TV video signatures. The methodology can detect and tag most or all RF transmissions across extended RF bands that are composed of a mixture of modulation types that occur simultaneously.

The methodology of certain embodiment herein may be executed in whole or in part by the processing components within an SDR, such as SDR 100. The nature of such devices is well known in the art and not discussed further herein. The invention is not limited to the nature of the SDR.

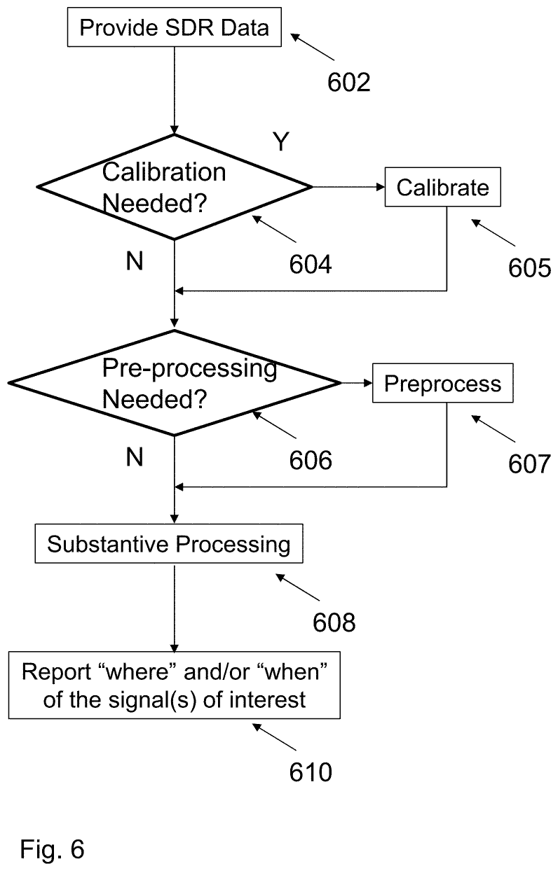

FIG. 6 shows a flowchart of an embodiment of the invention. At the front end of at step 602 the RF waterfall data is provided. As noted above, non-limiting examples of providing such data can be a direct copy of the SDR display, extracted by API software methods and/or extracted through IQ output from the SDR 100. The invention is not limited to how the SDR data is obtained or provided.

In some cases the data from SDR 100 may require calibration before substantive processing. By way of non-limiting example, calibration may be needed during the first few seconds of receiving the SDR data. In another non-limiting example, calibration may be needed if the frequency bands are changed. At step 604, the methodology determines if calibration is needed. If so, the SDR data proceeds to calibration step 605 for calibration using one or more various methods as discussed in more detail below, and then sent for further processing. If not, the SDR data proceeds bypasses calibration in favor of further processing.

After calibration, data may require pre-processing before substantive processing. By way of non-limiting example, waterfall data with gaps in the waterfall may require pre-processing whereas a steady stream of data may not. By way of another non-limiting example, waterfall data with low signal to noise ratio (e.g., extremely high noise from an electrical strike or a very weak signals relative to common noise levels) may require preprocessing. At step 606, the methodology determines if pre-processing is needed. If so, the SDR data proceeds to step 607 for pre-processing using one or more various methods as discussed in more detail below, and then the pre-processed data is sent for further processing. If not, the SDR data bypasses pre-processing in favor of further processing.

After any calibration and/or preprocessing data as above, the data undergoes substantive processing at step 608 where various operations are applied to extract the time, dimensions, and frequency locations of RF signals. The results of processing, which includes the “when” and/or “where” of any signals of interest with the data are then provided at step 610 for further use, such as by way of non-limiting example a Cognitive radio, signal classification, or generating a surveillance report.

Each part of these components shown in FIG. 6 will be discussed in detail in the following paragraphs.

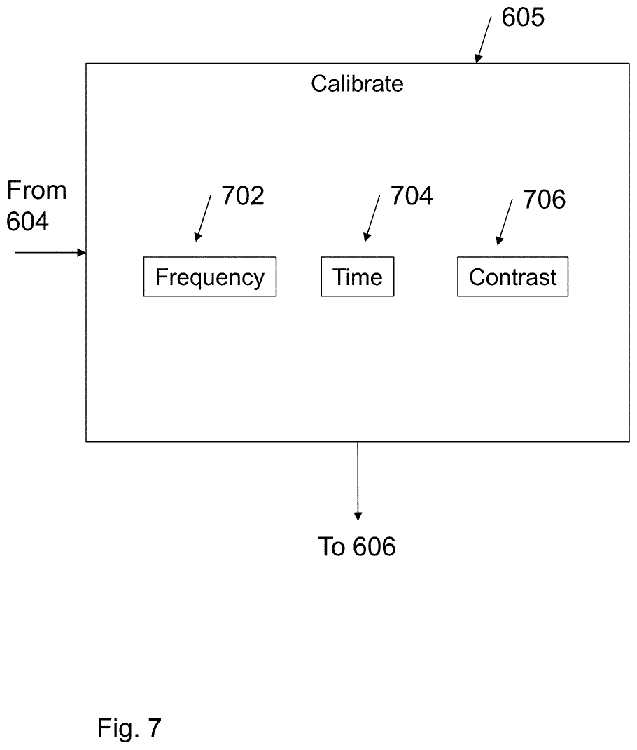

FIG. 7 shows the calibration step 605 in more detail. The calibration may include by way of non-limiting example frequency calibration 702), time calibration 704, and/or contrast calibration 706). Frequency calibration may be useful to map waterfall pixel coordinates into frequency locations. Time calibration may be useful to provide temporal markers as to when the transmission occurs. Contrast calibration may be useful to equate signal strength to gray-scale brightness and provide a method to improve detection performance. Some or all of these may be utilized in this embodiment. Other types of calibration could also be used. The invention is not limited to the types or nature of the calibration.

Frequency calibration refers to ensuring that signal measurements are taken at the correct frequencies. Absent frequency calibration, the measured frequency can be incorrect due to offset (e.g., the signal is at 700 kHz yet the measurements show 710 kHz) and scale (how much the display is showing widthwise for the signal band).

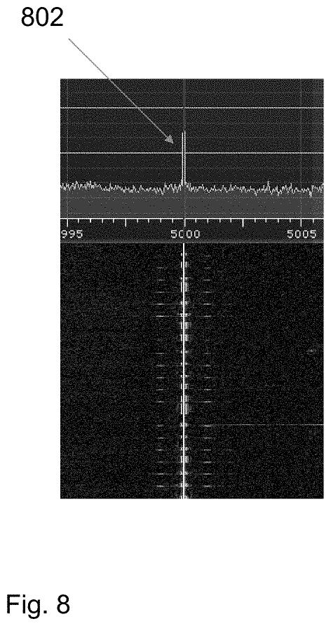

Referring now to FIG. 8, an embodiment of a methodology to calibrate the frequency offset is to inject known markers into the signal at known frequencies, such as the preexisting WWV signals broadcast on 10 MHz and 15 MHz; FIG. 8 by way of non-limiting example shows receipt of a WWV signal broadcast 802 on 5 MHz. If such preexisting beacons are not available, then a pre-calibrated signal generator can be used to inject a marker signal into the signal at a known frequency. If the observed peak(s) from the signal(s) are not displayed in the signal display at the expected/required location(s), then SDR 100 needs to be calibrated using the specific methodology for that device (as set forth in that device's operating manual). The invention is not limited to the nature of the offset frequency calibration.

An embodiment of a methodology to calibrate the scale is a regression technique associating pixel coordinates in the waterfall display as the dependent variable with labeled frequency location as the independent variable. The invention is not limited to the nature of the scale frequency calibration.

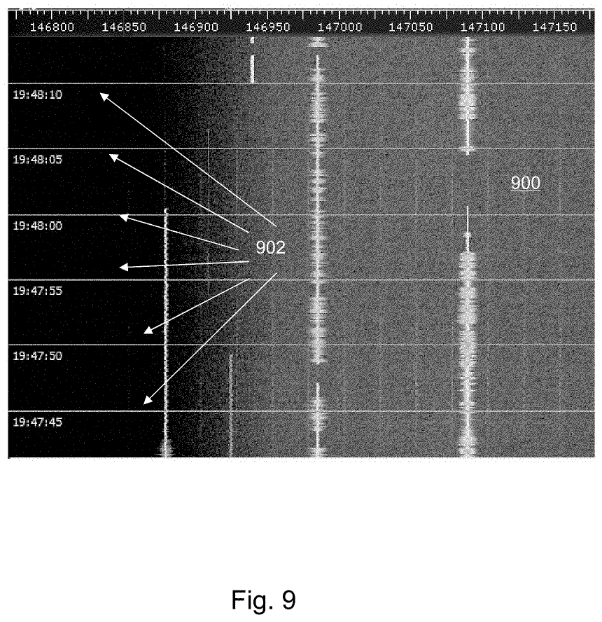

FIG. 9 illustrates an embodiment for calibrating the time vertical axis on the waterfall display. Time in this context refers to the rate at which the signal of interest is sampled from the waterfall. If the sampling rate is too high, gaps may appear in the waterfall that would trigger a need for pre-processing at steps 606/607. If the sampling rate is too low, then the waterfall may lack sufficient resolution to allow for accurate identification of the “where” and “when”.

There are a variety of possible approaches to time calibration. Non-limiting examples include the introduction of an internal clock within the SDR, or an external reference. An embodiment of a methodology to calibrate the time is a regression technique associating the Y-coordinate start or stop of an instance of the waterfall display as the dependent variable with time tags (discussed below) as the independent variable. The invention is not limited to the nature of the scale frequency calibration.

For the internal clock approach, many SDR devices are tied to the internet were accurate time tags can be acquired to label the signal. FIG. 9 shows this embodiment where horizontal read lines 902 are placed across the waterfall image 900 every 5 seconds. The specific time interval is not important as long it is sufficiently long to measure several pixels that span from the start of the time interval to its end. Counting the number of pixels between two points is a common procedure and will not be discussed here. Upon completion the time-scaling calibration, a scaling constant is determined having dimensions of pixels per second.

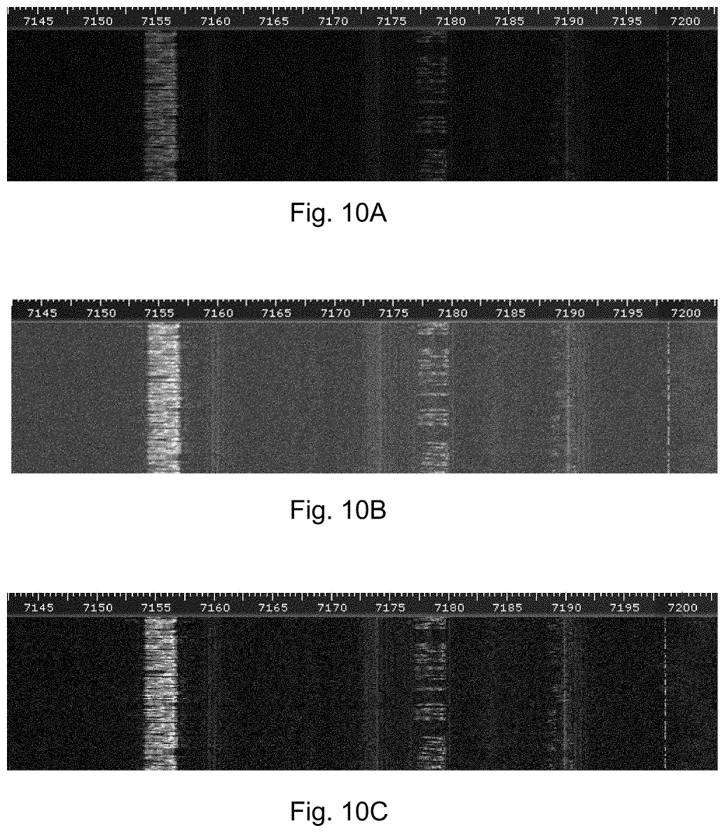

FIGS. 10A-C illustrates an embodiment as to how signal contrast calibration can be performed to ensure that the signals can be detected. This calibration sets the gain of the SDR 100 to a level that balances signal visibility with minimization of noise. If the gain of the SDR 100 is set low as in FIG. 10A, the display is almost black and only the strongest signals are visible across the waterfall display. At very high gain levels as in FIG. 10B the signals stand out strongly but there are now large amounts of fuzziness between the waterfall signals. A calibrated level such as shown in FIG. 10C balances the high clarity with minimal fuzziness between the waterfalls. One method to identify whether the image is too bright or too dark is based on standard deviation, in which a dark image or a bright image would both have low standard deviations of pixel intensity values, whereas a balanced image would have a high standard deviation. However the invention is not so limited, and other methods of signal contrast calibration can be used.

After any applied calibration is complete, the signal can either proceed to substantive processing at step 608, or be enhanced via pre-processing at steps 606/607. Non-limiting examples of pre-processing at step 607 may include, e.g., improving signal to noise ratio, removing environmental noise (e.g. a lightning strike), removing RF contamination from nearby equipment (e.g., a fluorescent light or power supply). However, the invention is not so limited and other types of pre-processing could also be applied.

The decision whether to proceed at step 606 to pre-processing at step 607 or bypass to substantive processing at step 608 depends on whether there is value via pre-processing in expanding the dynamic range in detecting very low-level signals which may otherwise be difficult to see on the waterfall display. For example, preprocessing at step 607 may be applied if at step 606 it is determined that the signal to noise ratio of the waterfall is below a threshold. In another example, preprocessing at step 607 may be applied if at step 606 it is determined that the waterfall data included content that was consistent with a lightning strike that needed to be removed. The invention is not limited to the criteria upon which the methodology elects or declines to proceed with pre-processing before substantive processing.

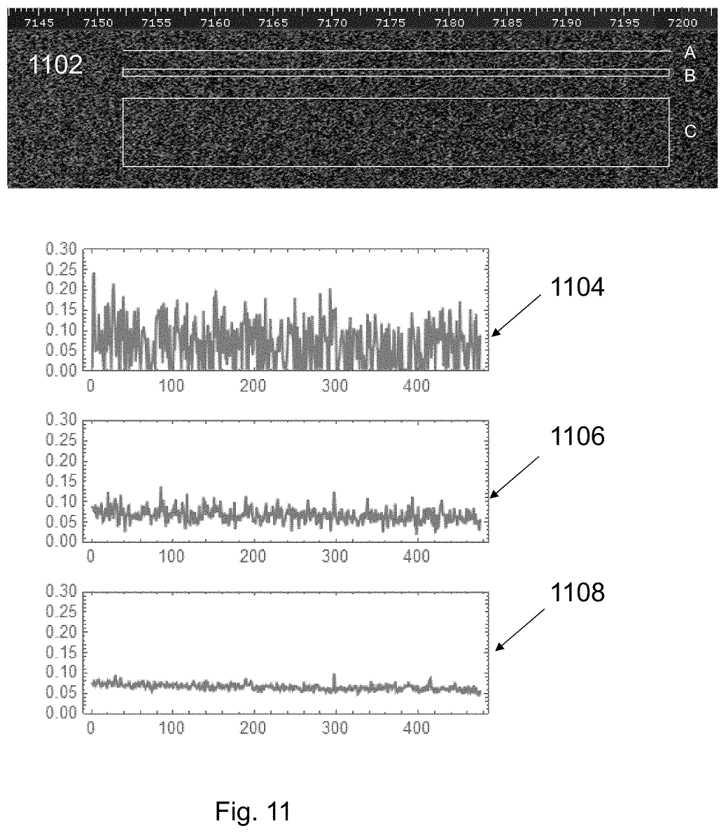

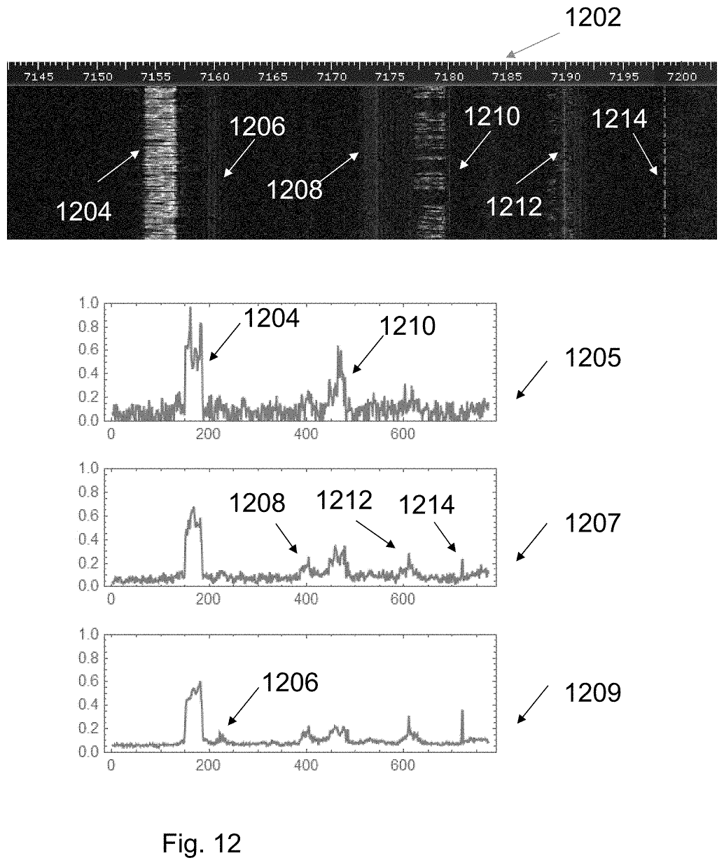

An embodiment of reducing the signal to noise ratio is shown in with respect to FIGS. 11 and 12. FIG. 11 shows a waterfall graph 1102 with no meaningful signal, and thus only sources of noise(s) are present (thereby displaying as background snow). Changes in the time over which the waterfall is averaged will reduce the influence of that noise. If the noise is across a single line (A), a possible realization is shown in graph 1104. If the noise is taken across a wider time region (B), the plotted average has become less bumpy but has a small bias on its floor as shown in graph 1106. If the noise is taken across an even wider time region in (C), the noise floor is even flatter, and the bias floor does not increase as shown in graph 1108.

FIG. 12 shows a situation where signals are present in the waterfall display as illustrated in graph 1202. Graph 1202 shows six (6) signals of interest: 1204, 1206, 1208, 1210, 1212 and 1214. Absent any preprocessing at 607, the averaging in graph 1202 with minimal time width as shown in graph 1205 only cleanly reveals the signals for 1204 and 1210, while the other signals are masked by noise. Graph 1207 uses a wider time frame for averaging (e.g. slice B in waterfall graph 1102), for which the signals for 1208, 1212 and 1214 start to become more visible, but signal 1206 is not while signals 1204 and 1210 are reducing in height. Graph 1309 uses an even wider time frame for averaging (e.g., slice C in waterfall graph 1102), in which now all six (6) signals are visible but the strongest signals at 1204 and 1210 have been significantly reduced.

Which graph 1205/1206/1209 is selected, and whether pre-processing occurs at all, is in part dependent upon what signal of interest is being looked for. If the signal of interest is 1204, then it is quite clear absent pre-processing and either graph 1205 could be used or no pre-processing need be used at all. If the signal of interest is 1206, then graph 1209 would be used as this is the level of signal-to-noise reduction is needed to reveal the signal. If both 1204 and 1206 are signals of interest, then graphs 1305 and 1309 could be used separately and each processed individually.

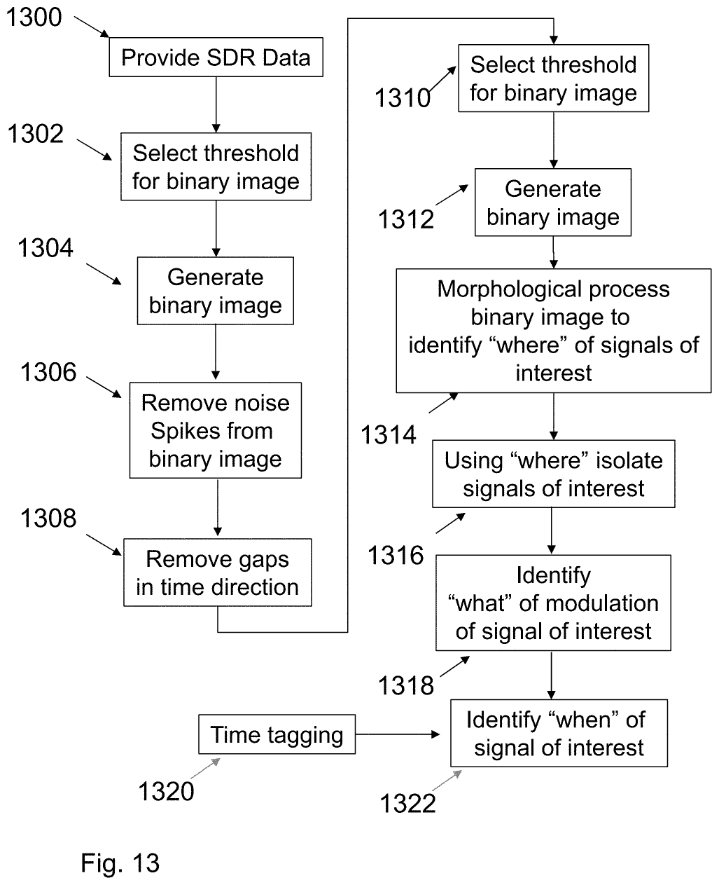

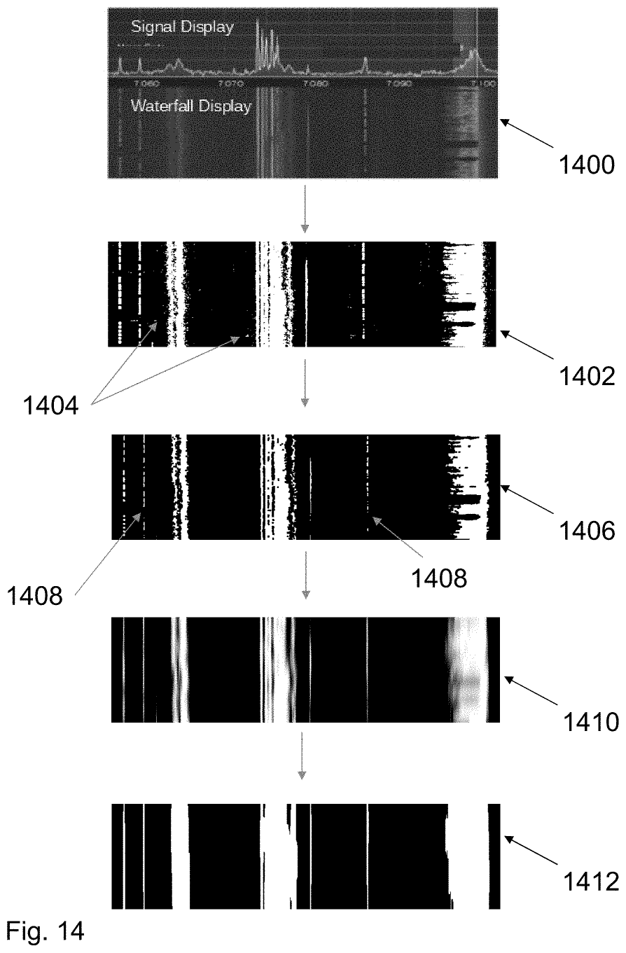

Regardless of whether the waterfall data is preprocessed or not, the processing engine can process and localize signal locations across the entire RF spectrum of interest at step 608. Referring now to FIGS. 13 and 14, an embodiment of such processing is shown. In step 1300, data for waterfall image 1400 is provided. This may be the raw waterfall data from step 602 (no preprocessing applied) or pre-processed waterfall data as it emerges from step 607. The invention is not limited to the nature of the waterfall data as provided and subsequently processed.

At step 1302, a threshold is selected to apply to the waterfall image data to produce a black and white binary image. The threshold could be selected by the user, or by a particular mathematical processing such as classic Otsu cluster variance maximization) or the Kapur (histogram entropy minimization) as known to those of skill in the art and not further discussed herein.

At step 1304, a binary image 1402 is generated from waterfall image 1400 by converting pixels in waterfall image 1400 with values below the threshold to black and pixels above the threshold to white (pixels with values at the threshold can convert to black or white depending upon the applied algorithm). This binary image shows regions of RF activity in white while the remaining background is black which is void of RF activity.

The binary image 1402 will likely include local areas of isolated white spots 1404 that are not associated to any RF activity and are simply localized noise spikes. These can be removed at step 1306 via known morphological erosion and/or morphological size filtering to provide a clean intermediate image 1406. The invention is not limited to the manner in which the noise spikes are identified and/or removed.

Due to the nature of the modulation some waterfalls may have gaps 1408 along the time direction (e.g. vertical direction). At step 1308 these gaps are removed. A non-limiting example of a gap removal method is to blur the image using a Y-direction smear to generate a blurred image 1410; preferably there is no smear applied to the horizontal (frequency direction) to promote maximum isolation from adjacent waterfall structures, but this not need be the case. The blurred image 1410 has continuous vertical lines in the waterfall that coincide with the signal(s) of interest. Other non-limiting examples of blurring methods include Fourier filtering and anisotropic dilution, although the invention is not limited to any specific blurring methodology.

By virtue of the blurring at step 1308, the blurred image 1410 is a gray-scale image that needs to convert back into a binary image for further processing. At step 1310, a second threshold is selected and at step 1312 applied to apply to the blurred image 1410 in the manner discussed at step 1304 to produce a black and white binary image 1412. The threshold could be selected by the user, or by a particular mathematical processing such as classic Otsu cluster variance maximization) or the Kapur (histogram entropy minimization) as known to those of skill in the art and not further discussed herein. Each contiguous white area of binary image 1412 represents a distinct RF activity for extraction.

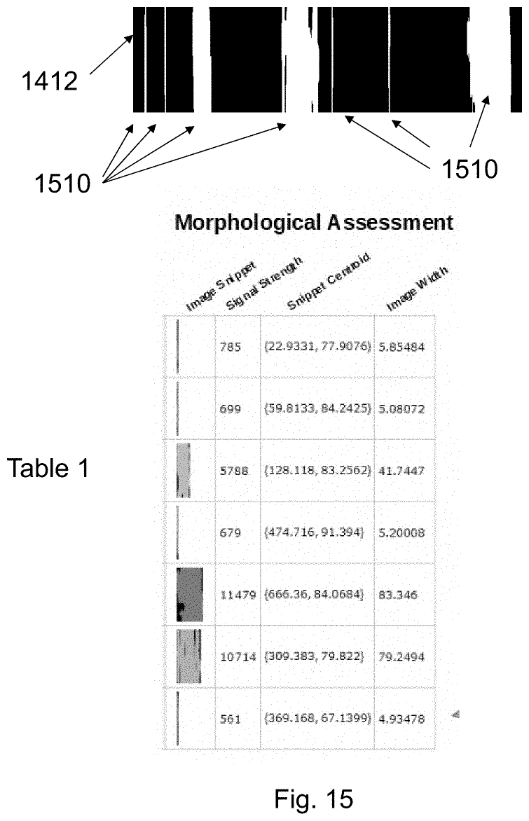

Identification of the “where” of the signals of interest in binary image 1412 occurs at step 1314. Referring now also to FIG. 15, the methodology tags binary signature regions identified in the binary image 1412. In the non-limiting example, binary image 1412 has seven (7) particular and distinct contiguous white segment regions 1510, hereafter referred to as segment regions, each of which corresponds to a signal of interest in waterfall image 1400. The morphological operations, for each segment region 1510, computes the corresponding pixel coverage (the number of pixels in each region, which generally represents the signals strength) and location.

Location, as based on spacial characteristics of each of the segment regions, can be for example the centroid location of the segment regions and its width as shown in Table 1, although the invention is not so limited and other location definition formats (e.g., frequency of left and right sides) could be used. A non-limiting example of a morphological operation that identifies the centroid (geographical center) of a particular segment region 1510 identifies the (x,y) position of every pixel in the white region, adds the values together and then divides the total sum x value and the total sum y value by the number of pixels in the corresponding segment region 1510. To identify the horizontal width, a “bounding box” methodology could be used to identify the largest horizontal width box that could fit within the corresponding segment region 1510 that includes only white pixels (and does not extend to include any black pixels outside). However, the invention is not so limited, another other morphological operations may also be used.

The location parameters (e.g., centroid information and width) from binary image 1412 provides direct information of ‘where” each of the received signal frequency is located in the original waterfall image 1400. This is because the horizontal location on the image is linearly related to the actual frequency of the signal.

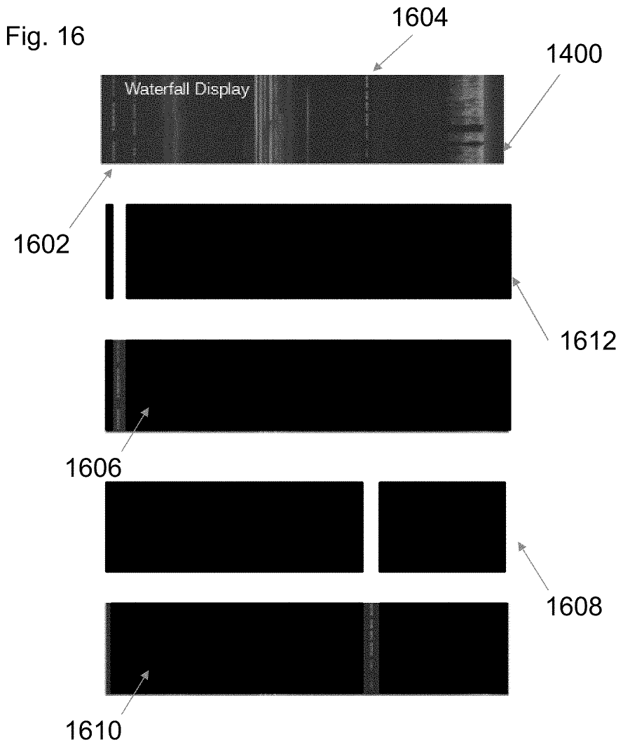

At step 1316, knowing the “where,” each signal of interest in waterfall image 1400 is isolated and extracted from the remainder of the waterfall image 1400 for further processing and ultimate identification. A non-limiting example of an extraction methodology would be to apply a “where” mask over the waterfall image 1400 that converts everything outside of the “where” of the signal of interest into black pixels. Referring now for example to FIG. 16, the leftmost signal of interest 1602 has a known centroid and width from the location parameters. Based on these location parameters, a mask 1612 is created that covers the waterfall image 1400 everywhere outside of that dictated by the location parameters, while exposing the signal of interest in waterfall image 1400; the dimensions of the mark may be absolute from the location parameters, or only based on the location parameters (e.g., rounding, adding buffers, or other further processing).

The mask 1612 is then combined (e.g., multiplied against with a pixel value of zero for the black) against the waterfall image 1400, thereby created a converted waterfall image 1606 with just the raw signal of interest 1602 with other content (including other signals of interest such as 1604) removed.

This extraction process repeats for each slice. For example, signal of interest 1604 will be combined with a mask 1608 based on the location parameters of signal of interest 1604, thereby a converted waterfall image 1610 with just the raw signal of interest 1604 with other content (including other signals of interest such as 1602) removed.

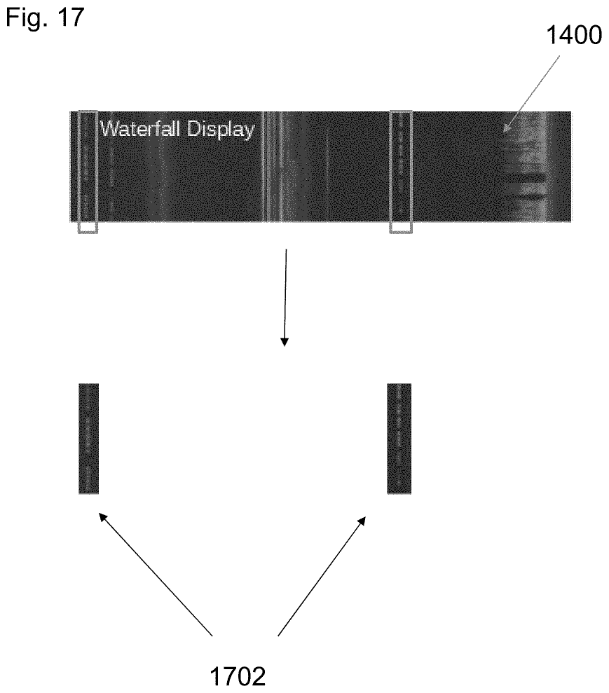

Referring now to FIG. 17, another isolating methodology is simply to cut out slices of from the waterfall image 1400 using the location parameters as the location and width of the slice. FIG. 17 shows two slices 1702 corresponding to signals of interest 1602 and 1604 as discussed with respect to FIG. 16.

At step 1318, the identified slice is subject to signal identification processing to identify “what” type of modulation type the signal of interest is. A methodology for doing so is disclosed in Kacenjar et al., Performance Assessment of a Machine-Learning-Derived Digital RF Communication Classifier, which is incorporated herein by reference in its entirety.

At step 1322, the “when” of the signal of interest, which can be identified. The methodology relies on a prior time tagging at step 1320 that provides a relationship between a Y-coordinate on the waterfall image and the specific time that the Y-coordinate corresponds. The timing of the time tagging processing is flexible, and can occur anytime before the “when” step of 1322.

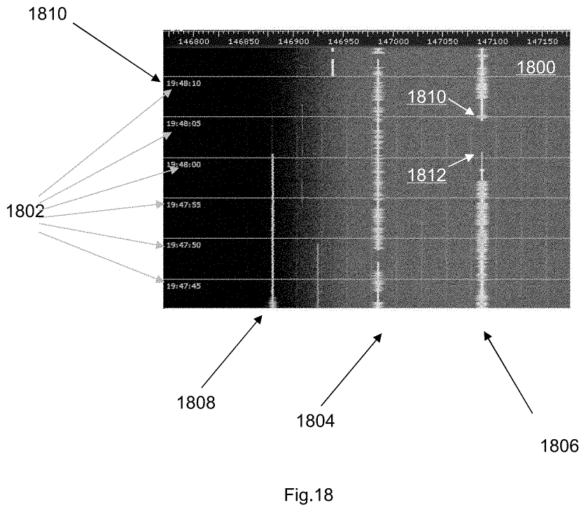

Referring now to FIG. 18, time tagging at step 1320 and “when” processing at step 1322 is discussed with respect to a waterfall image 1800 (which corresponds to waterfall image 1400 in the processing above, although waterfall image 1800 shows a different waterfall with signals more easily identifiable with respect to this “when” processing). Waterfall image 1800 includes signals of interest such as 1804, 1806 and 1808. The “when” processing will identify the start and stop times of these various signal of interest.

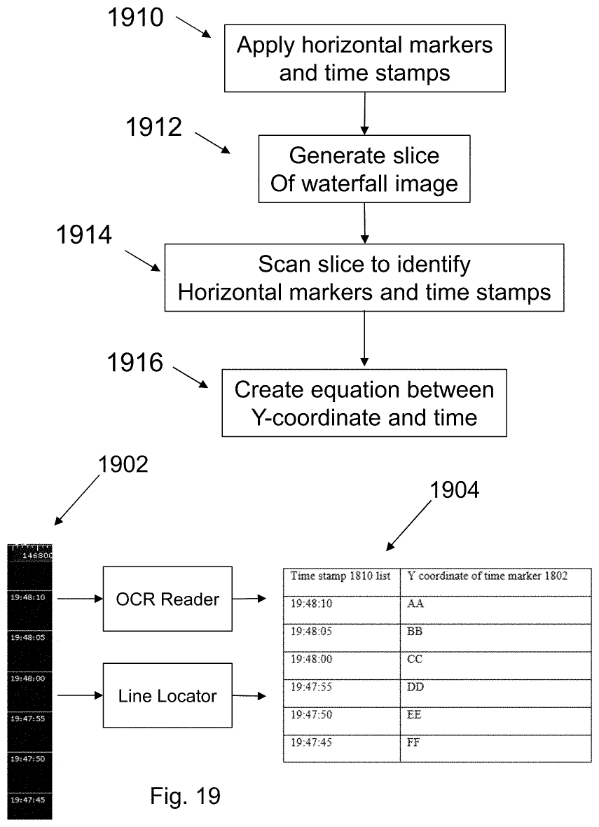

Referring now also to FIG. 19, to create the time tagging at step 1320, at step 1910 horizontal time markers 1802 are applied to the waterfall image 1800 at user or system defined intervals supported by the SDR 100; this may be performed early in the processing as part of the time calibration of SDR 100. By way of non-limiting example in FIG. 18, time markers 1802 are placed at defined time intervals of 5 seconds apart. Proximate to each time marker 1802 is a time stamp 1810 of the time corresponding to the sample of the signal that created the time marker 1802; for example in FIG. 18 the time of the highest time marker 1802 is the sample was taken at time 19:48:10.

At step 1912 a slice of the waterfall image 1800 corresponding to the time stamps 1810 and a portion of the time markers 1802 is isolated and extracted. At step 1914 slice 1900 is scanned, such as by an OCR reader, to convert the time stamps 1810 into a computer readable format. At step 1914 slice 1900 is also scanned by a line locator protocol such as known in the art to identify the Y-coordinate (represented generically by AA-FF) of each corresponding time marker 1802. The contents of 1904 gives a correlation between the location of specific time markers 1802 and the times that they occurred. This data can be subject to a regression analysis at step 1916 to define a mathematical relationship between the two, which may be linear or non-linear. From that equation, the time can be identified for any Y-coordinate in the waterfall image 1800.

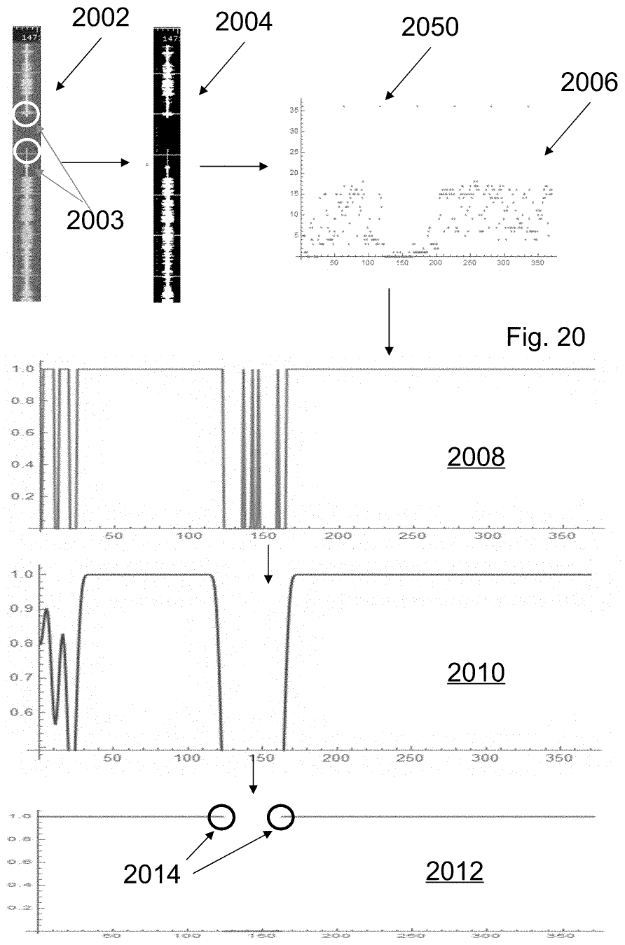

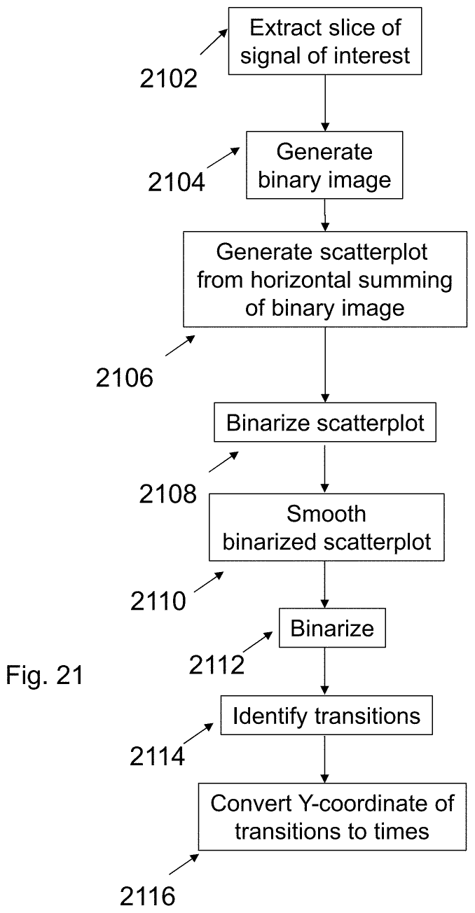

Referring now to FIGS. 20 and 21, for the “when” processing of step 1322, using the “where” information provided earlier in the methodology the signal of interest is extracted at step 2102 from the waterfall image 1800 (either including the time markers 1802 or omitting the same) to form a slice 2002. The ultimate goal of the “when” process is to identify the start and stop times of the signal as shown by 2003.

At step 2104 slice 2002 is converted to a binary image 2004. At step 2106 binary image 2004 is subject to horizontal summing to create a scatterplot 2006 of summed values. The X-axis of the scatterplot 2006 represents the Y coordinate of the slice 2002, and the Y-axis of the scatterplot 2006 represents the summed value across that Y-coordinate. In this example which included the time markers 1802 in waterfall image 1800, the summed value is at a maximum 2050 as all pixels along that Y-coordinate are white, thus producing the highest available summed value.

At step 2108 the points on the scatterplot 2006 are binarized into one of two values (e.g., zero and one) relative to a threshold to produce a first binarized realization 2008 of the scatterplot. The transitions between the two binary levels in first binarized realization 2008 represent gaps in the waterfall of slice 2002.

Some gaps, particularly larger ones, are typically the result of the stop and start of the signal interest. Other gaps, typically smaller ones, are often just gaps in the transmission process (e.g., spaces between Morse Code, or an active voice signal where no one is speaking). The methodology distinguishes between the two at step 2110 by applying a smoothing operation to the first binarized realization 2008 of the scatterplot. A non-limiting example of such a smoothing operation is sliding average utilizing local binning, although the invention is not limited to any particular smoothing operations.

The smoothing operation produces a graph 2010. This graph 2010 is then binarized at step 2112 to generate a second binarized realization 2012 of the graph 2010. Unlike the first binarized realization 2008 that included transitions corresponding to gaps for both start/stop and in-signal pauses, second binarized realization 2012 preferably only transitions for long gaps that are consistent with the start and stop 2014. At step 2114 those transitions are identified to produce the Y-coordinates of the start and stop 2014 of the signal of interest, where the left side of the gap is the stop and the right side of the gap corresponds to a start. At step 2116 the equation from the time tagging (FIG. 19) is applied to convert the Y-coordinates to time, thereby producing the corresponding time of the start and stop 2003 of the signal of interest within slice 2002. The “when” of a signal is defined by the resulting time information, such as the time the signal starts and its duration.

The above methodologies provide an automatic way to analyze a waterfall image and generate the “what,” “where” and/or “when” information for signals of interest within the waterfall image.

In embodiments where the computing device includes a Web server, the Web server can run any of a variety of server or mid-tier applications, including HTTP servers, FTP servers, CGI servers, data servers, Java servers, and business application servers. The server(s) also may be capable of executing programs or scripts in response requests from user devices, such as by executing one or more Web applications that may be implemented as one or more scripts or programs written in any programming language, such as Java®, C, C# or C++, or any scripting language, such as Perl, Python, or TCL, as well as combinations thereof. The server(s) may also include database servers, including without limitation those commercially available from Oracle®, Microsoft®, Sybase®, and IBM®.

The environment can include a variety of data stores and other memory and storage media as discussed above. These can reside in a variety of locations, such as on a storage medium local to (and/or resident in) one or more of the computers or remote from any or all the computers across the network. In a set of embodiments, the information may reside in a storage-area network (“SAN”) familiar to those skilled in the art. Similarly, any necessary files for performing the functions attributed to the computers, servers, or other network devices may be stored locally and/or remotely, as appropriate. Where a system includes computerized devices, each such device can include hardware elements that may be electrically coupled via a bus, the elements including, for example, at least one central processing unit (CPU), at least one input device (e.g., a mouse, keyboard, controller, touch screen, or keypad), and at least one output device (e.g., a display device, printer, or speaker). Such a system may also include one or more storage devices, such as disk drives, optical storage devices, and solid-state storage devices such as random-access memory (“RAM”) or read-only memory (“ROM”), as well as removable media devices, memory cards, flash cards, etc.

Such devices also can include a computer-readable storage media reader, a communications device (e.g., a modem, a network card (wireless or wired), an infrared communication device, etc.), and working memory as described above. The computer-readable storage media reader can be connected with, or configured to receive, a computer-readable storage medium, representing remote, local, fixed, and/or removable storage devices as well as storage media for temporarily and/or more permanently containing, storing, transmitting, and retrieving computer-readable information. The system and various devices also typically will include several software applications, modules, services, or other elements located within at least one working memory device, including an operating system and application programs, such as a client application or Web browser. It should be appreciated that alternate embodiments may have numerous variations from that described above. For example, customized hardware might also be used and/or particular elements might be implemented in hardware, software (including portable software, such as applets), or both. Further, connection to other computing devices such as network input/output devices may be employed.

Storage media and computer readable media for containing code, or portions of code, can include any appropriate media known or used in the art, including storage media and communication media, such as but not limited to volatile and non-volatile, removable and non-removable media implemented in any method or technology for storage and/or transmission of information such as computer readable instructions, data structures, program modules, or other data, including RAM, ROM, EEPROM, flash memory or other memory technology, CD-ROM, digital versatile disk (DVD) or other optical storage, magnetic cassettes, magnetic tape, magnetic disk storage or other magnetic storage devices, or any other medium which can be used to store the desired information and which can be accessed by a system device. Based on the disclosure and teachings provided herein, an individual of ordinary skill in the art will appreciate other ways and/or methods to implement the various embodiments.

In an embodiment, this engine can be run automatically and populate a database in real-time with recorded and analyzed activity. Waterfall image captures can be directed by a scripting program which then captures and processes the information. Capture and processing can be continuous, scheduled (e.g., when certain frequencies are known to be in use), and/or on demand.

The above embodiments are described with respect to certain representations of pixels being white or black. However, the invention is not so limited, and reversed orientations with black/white could also be used.

The various waterfall images discussed herein are shown and discussed as black and white. However, the invention is not so limited, and color versions of waterfall images are known and used. For a color waterfall image, then the color waterfall image could be converted into greyscale using known techniques, and then converted into binary images as discussed above.

The above embodiments are discussed with respect to white and black processing. However, the invention is not so limited, and other color pairs (e.g., white/blue, blue/red, etc.) The basic methodology of FIG. 11 would still apply, perhaps not including using a greyscale conversion. In this case the binary image goes to two color extremes rather than black/white as in the examples above.

The specification and drawings are, accordingly, to be regarded in an illustrative rather than a restrictive sense. It will, however, be evident that various modifications and changes may be made thereunto without departing from the broader spirit and scope of the invention as set forth in the claims.

What is claimed is:

1. A method, comprising:
converting a waterfall image into a first binary image version of the waterfall image;
removing noise spikes from the first binary image version of the waterfall image;
removing vertical gaps in the first binary image to thereby create an intermediate image version of the first binary image;
converting the intermediate image version of the first binary image into a second binary image;
identifying location parameters of a signal of interest within the second binary image; and
isolating, using the identified location parameters, the signal of interest in the waterfall image to generate an isolated image of the signal of interest.

2. The method of claim 1, wherein the identifying within the second binary image the location parameters of signals of interest comprises:
identifying spacial characteristics of a distinct contiguous white region within the second binary image, the distinct contiguous region corresponding to the signal of interest; and
determining the location parameters for the distinct contiguous white region.

3. The method of claim 2, wherein the isolating, using the identified location parameters, the signals of interest in the waterfall image comprises:
generating, from the location parameters for the distinct contiguous white region, a mask that exposes a portion of the distinct contiguous white region within the second binary image, and covers a remainder of the second binary image; and
combining the mask and the waterfall image to generate the isolated image.

4. The method of claim 2, wherein the isolating, using the identified location parameters, the signal of interest in the waterfall image comprises:
extracting a portion of the waterfall image based on the determined location parameters to generate the isolated image.

5. The method of claim 1, further comprising determining, from at least the isolated image of the signal of interest, a type of modulation of the signal of interest.

6. The method of claim 1, further comprising determining from at least the isolated image of the signal of interest when the signal of interest occurred.

7. The method of claim 1, further comprising:
repeating the identifying and isolating for other signals of interest in the second binary image.

8. A non-transitory computer readable storage media containing instructions to cause a system, including electronic computer hardware and software, to perform operations comprising:
converting a waterfall image into a first binary image version of the waterfall image;
removing noise spikes from the first binary image version of the waterfall image;
removing vertical gaps in the first binary image to thereby create an intermediate image version of the first binary image;
converting the intermediate image version of the first binary image into a second binary image;
identifying location parameters of a signal of interest within the second binary image; and
isolating, using the identified location parameters, the signal of interest in the waterfall image to generate an isolated image of the signal of interest.

9. The non-transitory computer readable storage media of claim 8, wherein the identifying within the second binary image the location parameters of signals of interest comprises:
identifying spacial characteristics of a distinct contiguous white region within the second binary image, the distinct contiguous region corresponding to the signal of interest; and
determining the location parameters for the distinct contiguous white region.

10. The non-transitory computer readable storage media of claim 9, wherein the isolating, using the identified location parameters, the signals of interest in the waterfall image comprises:
generating, from the location parameters for the distinct contiguous white region, a mask that exposes a portion of the distinct contiguous white region within the second binary image, and covers a remainder of the second binary image; and
combining the mask and the waterfall image to generate the isolated image.

11. The non-transitory computer readable storage media of claim 9, wherein the isolating, using the identified location parameters, the signal of interest in the waterfall image comprises:
extracting a portion of the waterfall image based on the determined location parameters to generate the isolated image.

12. The non-transitory computer readable storage media of claim 8, the operations further comprising determining, from at least the isolated image of the signal of interest, a type of modulation of the signal of interest.

13. The non-transitory computer readable storage media of claim 8, the operations further comprising determining from at least the isolated image of the signal of interest when the signal of interest occurred.

14. The non-transitory computer readable storage media of claim 8, the operations further comprising:
repeating the identifying and isolating for other signals of interest in the second binary image.

15. A system, comprising:
a non-transitory computer readable storage media containing instructions;
a processor programmed to cooperate with the instructions to cause the system to perform operations comprising:
converting a waterfall image into a first binary image version of the waterfall image;
removing noise spikes from the first binary image version of the waterfall image;
removing vertical gaps in the first binary image to thereby create an intermediate image version of the first binary image;
converting the intermediate image version of the first binary image into a second binary image;
identifying location parameters of a signal of interest within the second binary image; and
isolating, using the identified location parameters, the signal of interest in the waterfall image to generate an isolated image of the signal of interest.

16. The system of claim 15, wherein the identifying within the second binary image the location parameters of signals of interest comprises:
identifying spacial characteristics of a distinct contiguous white region within the second binary image, the distinct contiguous region corresponding to the signal of interest; and
determining the location parameters for the distinct contiguous white region.

17. The system of claim 16, wherein the isolating, using the identified location parameters, the signals of interest in the waterfall image comprises:
generating, from the location parameters for the distinct contiguous white region, a mask that exposes a portion of the distinct contiguous white region within the second binary image, and covers a remainder of the second binary image; and
combining the mask and the waterfall image to generate the isolated image.

18. The system of claim 16, wherein the isolating, using the identified location parameters, the signal of interest in the waterfall image comprises:
extracting a portion of the waterfall image based on the determined location parameters to generate the isolated image.

19. The system of claim 15, the operations further comprising determining, from at least the isolated image of the signal of interest, a type of modulation of the signal of interest.

20. The system of claim 15, the operations further comprising determining from at least the isolated image of the signal of interest when the signal of interest occurred.

21. The system of claim 15, the operations further comprising:
repeating the identifying and isolating for other signals of interest in the second binary image.
